(19) United States
(12) Patent Application Publication
(10) Pub. No.: US 2024/0309551 A1
(43) Pub. Date: Sep. 19, 2024

(54) MANUFACTURING DEVICE AND MANUFACTURING METHOD FOR GROUP III NITRIDE CRYSTAL

(71) Applicant: Panasonic Holdings Corporation, Osaka (JP)

(72) Inventors: JUNICHI TAKINO, Osaka (JP); MASAYUKI HOTEIDA, Osaka (JP); SHUNICHI MATSUNO, Kyoto (JP)

(21) Appl. No.: 18/669,579

(22) Filed: May 21, 2024

Related U.S. Application Data
(63) Continuation of application No. PCT/JP2022/039053, filed on Oct. 20, 2022.

(30) Foreign Application Priority Data
Nov. 26, 2021 (JP) 2021-192457

(51) Int. Cl. C30B 25/14; C30B 25/08; C30B 29/40

(52) U.S. Cl. CPC C30B 25/14; C30B 25/08; C30B 29/406

(57) ABSTRACT

A device for producing a group III nitride crystal includes a raw material chamber that generates a group III element oxide gas and a growth chamber that reacts the group III element oxide gas supplied from the raw material chamber with a nitrogen element-containing gas to generate a group III nitride crystal on a seed substrate, wherein the raw material chamber includes a raw material reaction room and a multistage raw material boat that includes stages, is provided in the raw material reaction room, is filled with a starting group III element source, and causes a reactive gas to flow to react with the starting group III element source to generate a group III element oxide gas, and the multistage raw material boat includes, in each of the stages, at least two or more passages through which gas can flow.

### TECHNICAL FIELD

The present disclosure relates to a device and a method for producing a group III nitride crystal.

### BACKGROUND ART

The group III nitride crystal such as GaN is expected to be applied to next-generation optical devices such as a high-output LED (light emitting diode) and an LD (laser diode), and next-generation electronic devices such as a high-output power transistor mounted on an EV (electric vehicle), a PHV (plug-in hybrid vehicle), and the like. As a method for producing a group III nitride crystal, an oxide vapor phase epitaxy (OVPE) method using a group III oxide as a raw material is used (see, for example, PTL 1). An example of the reaction system in the OVPE method is as follows.
(1) Ga is heated, and in this state, H₂O gas is introduced. The introduced H₂O gas reacts with Ga to generate Ga₂O gas (Formula (I)).
(2) Then, an NH₃ gas is introduced, and the NH₃ gas is caused to react with the generated Ga₂O gas to generate a GaN crystal on a seed substrate (Formula (II)).

2Ga(1)+H₂O(g)→Ga₂O(g)+H₂(g) (I)

Ga₂O(g)+2NH₃(g)→2GaN(s)+H₂O(g)+2H₂(g) (II)

### CITATION LIST

### Patent Literature

PTL 1: WO 2015/053341 A

### SUMMARY OF THE INVENTION

A device for producing a group III nitride crystal according to one aspect of the present disclosure includes a raw material chamber that generates a group III element oxide gas and a growth chamber that reacts the group III element oxide gas supplied from the raw material chamber with a nitrogen element-containing gas to generate a group III nitride crystal on a seed substrate, wherein the raw material chamber includes a raw material reaction room and a multistage raw material boat that includes stages, is provided in the raw material reaction room, is filled with a starting group III element source, and causes a reactive gas to flow to react with the starting group III element source to generate the group III element oxide gas, and the multistage raw material boat includes, in each of the stages, at least two or more channel pipes through which the reactive gas can flow, the at least two or more channel pipes connecting the stage to an adjacent stage among the stages.

A method for producing a group III nitride crystal according to one aspect of the present disclosure includes reacting a group III element source with a reactive gas to generate a group III element oxide gas and reacting the group III element oxide gas with a nitrogen element-containing gas to generate a group III nitride crystal on a seed substrate, wherein in generation of the group III element oxide gas, a flow amount of a carrier gas flowing in addition to the group III element source and the reactive gas is reduced to suppress a flow rate of the reactive gas.

### BRIEF DESCRIPTION OF THE DRAWINGS

FIG. 1 is a schematic sectional view illustrating a sectional configuration of a device for producing a group III nitride crystal according to a first exemplary embodiment of the present disclosure.

FIG. 2 is a flowchart illustrating a method for producing a group III nitride crystal according to the first exemplary embodiment of the present disclosure.

FIG. 3A is a schematic sectional view illustrating an example of a structure of a multistage raw material boat.

FIG. 3B is a schematic sectional view illustrating an example in which each stage of the raw material boat in FIG. 3A is filled with Ga.

FIG. 4 is a schematic sectional view illustrating an example of a case where a multistage raw material boat is installed in a raw material reaction room.

Part (a) of FIG. 5 is a conceptual surface view of a Ga-filled surface side of a raw material boat, and part (b) of FIG. 5 is a conceptual sectional view of the raw material boat.

FIG. 6 is a schematic sectional view illustrating an example of a structure in which a reactive gas flows in parallel from the upstream side to the downstream side in a multistage raw material boat.

FIG. 7 is a schematic sectional view illustrating an example of a structure in which a reactive gas flows in series from the upstream side to the downstream side in a multistage raw material boat and flows back in a raw material reaction room.

FIG. 8 is a graph illustrating a Ga supply amount and a value of a half width (FWHM) of an X-ray rocking curve (XRC) in GaN (0002) in Comparative Examples 1 to 3 and Example 1.

FIG. 9 is a graph illustrating a Ga supply amount and a growth rate of a GaN crystal in Comparative Examples 1 to 3 and Example 1.

### DESCRIPTION OF EMBODIMENT

In the production method described in PTL 1, the reaction of Formula (I) does not sufficiently occur due to H₂O gas passing through the upper portion of Ga, and it is difficult to generate a desired amount of Ga₂O gas. Further, when unreacted H₂O gas is supplied onto the seed substrate or the GaN crystal being grown, the unreacted H₂O gas reacts with Ga₂O gas, and solid Ga₂O₃ is generated, so that there is also a problem that crystal quality deteriorates.

An object of the present disclosure is to provide a device and a method for producing a group III nitride crystal capable of producing a high-quality group III nitride crystal with high productivity by sufficiently reacting a starting group III element source with a reactive gas.

A device for producing a group III nitride crystal according to a first aspect includes a raw material chamber that generates a group III element oxide gas and a growth chamber that reacts the group III element oxide gas supplied from the raw material chamber with a nitrogen element-containing gas to generate a group III nitride crystal on a seed substrate, wherein the raw material chamber includes a raw material reaction room and a multistage raw material boat that includes stages, is provided in the raw material reaction room, is filled with a starting group III element source, and causes a reactive gas to flow to react with the starting group III element source to generate the group III element oxide gas, and the multistage raw material boat includes, in each of the stages, at least two or more channel pipes through which the reactive gas can flow, the at least two or more channel pipes connecting adjacent the stage to an adjacent stage among the stage.

A device for producing a group III nitride crystal according to a second aspect is the device for producing a group III nitride crystal according to the first aspect, wherein the reactive gas passing inside the raw material chamber may flow from an upstream side to a downstream side in the raw material reaction room, and the multistage raw material boat may include, in each stage, a passage through which the reactive gas flows, the passage being disposed from an upstream low-temperature side toward a downstream high-temperature side of the raw material reaction room.

A device for producing a group III nitride crystal according to a third aspect is the device for producing a group III nitride crystal according to the first or second aspect, wherein the multistage raw material boat may satisfy relationships of Formulas (1) to (5):

$$\frac{{d}_{G a N} \times W \times t}{[ G a N ]} < {\sum }_{m = 1}^{k} \frac{{d}_{G a} \times ( {S}_{m} - {n}_{m} \times {T}_{m} ) \times {l}_{m}}{[ G a ] \times y} \qquad ( 1 )$$

$${l}_{m} < {L}_{m} \qquad ( 2 )$$

$$1 \leq m \leq k \qquad ( 3 )$$

$${T}_{m} < \frac{{S}_{m}}{{n}_{m}} \qquad ( 4 )$$

$${n}_{m} \geq 2 \qquad ( 5 )$$

where d_{GaN} is a mass density of gallium nitride, d_{Ga} is a mass density of gallium, [GaN] is a molecular weight of gallium nitride, [Ga] is an atomic weight of gallium, W a surface area of a wafer, t is a thickness of a grown GaN crystal, Sₘ is a surface area of the raw material boat of a m-th stage, nₘ is a number of channel pipes of the raw material boat of the m-th stage, Tₘ is a sectional area of the channel pipe of the raw material boat of the m-th stage, lₘ is a height of the raw material boat of the m-th stage, y is a yield of Ga in GaN crystal growth, and k is a total number of stages of the multistage raw material boat.

A device for producing a group III nitride crystal according to a fourth aspect is the device for producing a group III nitride crystal according to any one of the first to third aspect, wherein the multistage raw material boat may have a structure in which the at least two or more channel pipes of the respective stages are not at positions that coincide with the at least two or more channel pipes of the stage with respect to a vertically adjacent stage among the stages in plan view.

A device for producing a group III nitride crystal according to a fifth aspect is the device for producing a group III nitride crystal according to any one of the first to fourth aspect, wherein a sectional area Tₘ of each of the at least two or more channel pipes may be less than or equal to 100 mm².

A method for producing a group III nitride crystal according to a sixth aspect includes reacting a group III element source with a reactive gas to generate a group III element oxide gas and reacting the group III element oxide gas with a nitrogen element-containing gas to generate a group III nitride crystal on a seed substrate, wherein in generation of the group III element oxide gas, a flow amount of a carrier gas flowing in addition to the group III element source and the reactive gas is reduced to suppress a flow rate of the reactive gas.

According to the device and the method for producing a group III nitride crystal according to an aspect of the present disclosure, a group III element source and a reactive gas can be sufficiently reacted, and a high-quality group III nitride crystal can be produced with high productivity.

Hereinafter, a device and a method for producing a group III nitride crystal according to exemplary embodiments will be described with reference to the accompanying drawings. In the drawings, substantially the same members are designated by the same reference marks.

### Outline of Device for Producing Group III Nitride Crystal

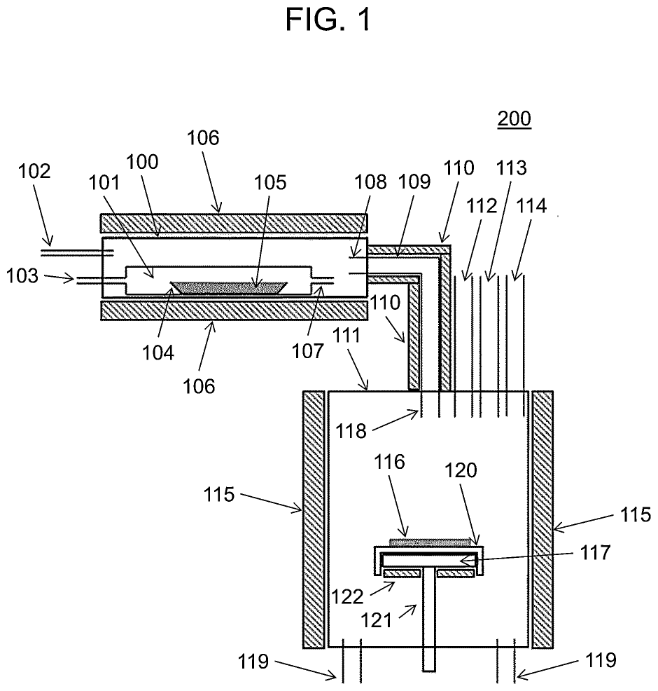

An outline of device 200 for producing a group III nitride crystal according to a first exemplary embodiment of the present disclosure will be described with reference to a schematic view of FIG. 1. FIG. 1 is a schematic sectional view illustrating a sectional configuration of device 200 for producing a group III nitride crystal according to the first exemplary embodiment. FIG. 1 is a schematic view, and the size, ratio, and the like of each component may be different from the actual size, ratio, and the like.

Device 200 for producing a group III nitride crystal according to the first exemplary embodiment includes raw material chamber 100 that generates a group III element oxide gas, and growth chamber 111 that generates a group III nitride crystal on a seed substrate. Raw material reaction room 101 is disposed in raw material chamber 100, and raw material boat 104 on which starting group III element source 105 is placed is disposed in raw material reaction room 101. In the present exemplary embodiment, starting group III element source 105 is a starting Ga source. Raw material reaction room 101 is connected with reactive gas supply pipe 103 that supplies a reactive gas that reacts with starting group III element source 105. Raw material reaction room 101 includes group III element oxide gas discharge port 107. When starting group III element source 105 is an oxide, a reducing gas is used as the reactive gas. When starting group III element source 105 is a metal, an oxidizing gas is used as the reactive gas. Raw material chamber 100 is provided with first carrier gas supply port 102. A first carrier gas supplied from first carrier gas supply port 102 carries the group III element oxide gas discharged from group III element oxide gas discharge port 107, from gas discharge port 108 through connection pipe 109 to growth chamber 111.

Growth chamber 111 includes gas supply port 118 that supplies the group III element oxide gas and the first carrier gas, third carrier gas supply port 112, nitrogen element-containing gas supply port 113, second carrier gas supply port 114, and discharge port 119. Substrate tray 120 on which seed substrate 116 is placed is disposed in growth chamber 111. Substrate tray 120 is placed on substrate susceptor 117, and substrate susceptor 117 is placed on rotary shaft 121. Fourth heater 122 is provided below substrate susceptor 117.

In the device for producing a group III nitride crystal according to the first exemplary embodiment of the present disclosure, raw material boat 104 in raw material reaction room 101 has a multistage structure, and has a structure in which a reactive gas flows in series from the upstream side to the downstream side, and passages of the reactive gas in the respective stages are parallel. This can improve the contact probability between the reactive gas and the starting group III element source 105, increase the generation amount of the group III element oxide gas, and improve the growth rate of the group III nitride crystal. In addition, since the amount of unreacted reactive gas supplied onto seed substrate 116 and the group III nitride crystal being grown is reduced, the quality of the group III nitride crystal can improve. The quality and productivity of the group III nitride crystal can thus improve.

### Outline of Method for Producing Group III Nitride Crystal

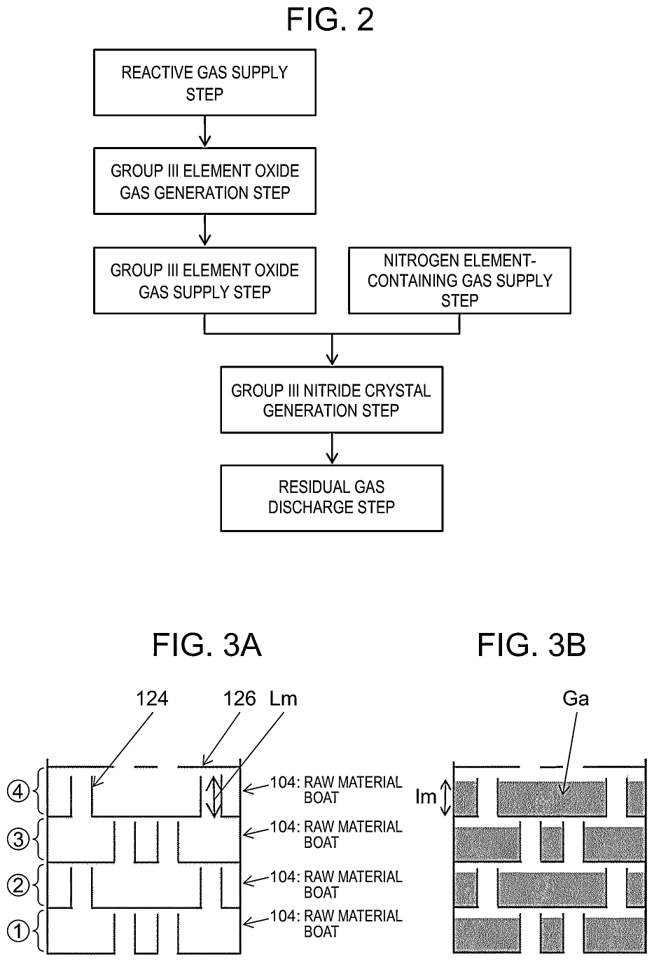

An outline of a method for producing a group III nitride crystal according to the first exemplary embodiment of the present disclosure will be described with reference to the flowchart of FIG. 2. The method for producing a group III nitride crystal according to the first exemplary embodiment includes a reactive gas supply step, a group III element oxide gas generation step, a group III element oxide gas supply step, a nitrogen element-containing gas supply step, a group III nitride crystal generation step, and a residual gas discharge step.

In the reactive gas supply step, a reactive gas is supplied from reactive gas supply pipe 103 to raw material reaction room 101 in raw material chamber 100. As described above, as the reactive gas, a reducing gas or an oxidizing gas may be used as necessary.

In the group III element oxide gas generation step, starting group III element source 105 is caused to react with the reactive gas (reducing gas when the starting group III element source is an oxide, oxidizing gas when the starting group III element source is a metal) in raw material reaction room 101 to generate a group III element oxide gas.

In the group III element oxide gas supply step, the group III element oxide gas produced in the group III element oxide gas generation step is supplied to growth chamber 111. The group III element oxide gas is discharged from the inside of raw material reaction room 101 through group III element oxide gas discharge port 107, discharged from gas discharge port 108 together with the first carrier gas supplied from first carrier gas supply port 102, carried through connection pipe 109, and supplied from gas supply port 118 into growth chamber 111.

In the nitrogen element-containing gas supply step, a nitrogen element-containing gas is supplied from nitrogen element-containing gas supply port 113 to growth chamber 111.

In the group III nitride crystal generation step, the group III element oxide gas supplied into growth chamber 111 in the group III element oxide gas supply step and the nitrogen element-containing gas supplied into growth chamber 111 in the nitrogen element-containing gas supply step are caused to react to grow a group III nitride crystal on seed substrate 116.

In the residual gas discharge step, unreacted gas that does not contribute to generation of the group III nitride crystal is discharged from discharge port 119 to the outside of growth chamber 111.

In the flowchart, the steps are indicated with arrows between the steps, but in practice, the steps illustrated in the flowchart may be performed simultaneously. The flowchart is illustrated with arrows from a step performed upstream to a step performed downstream in the device for producing a group III nitride crystal.

### Details of Method and Device for Producing Group III Nitride Crystal

Details of the method for producing a group III nitride crystal according to the first exemplary embodiment will be described. In the first exemplary embodiment, metal Ga is used as starting group III element source 105.

In the reactive gas supply step, reactive gas is supplied from reactive gas supply pipe 103 to raw material reaction room 101. In the example of the first exemplary embodiment, since metal Ga is used as starting group III element source 105, H₂O gas is used as the reactive gas. As the reactive gas, O₂ gas, CO gas, NO gas, N₂O gas, NO₂ gas, or N₂O₄ gas may be used.

In the group III element oxide gas generation step, the reactive gas supplied to raw material reaction room 101 in the reactive gas supply step reacts with Ga as starting group III element source 105 to generate Ga₂O gas as a group III element oxide gas. The produced Ga₂O gas is discharged from raw material reaction room 101 to raw material chamber 100 via group III element oxide gas discharge port 107. The discharged Ga₂O gas is mixed with the first carrier gas supplied from first carrier gas supply port 102 to raw material chamber 100 and is supplied to gas discharge port 108.

In the first exemplary embodiment, first heater 106 heats raw material chamber 100. When raw material chamber 100 is heated, the temperature of raw material chamber 100 is preferably more than or equal to 800° C., which is higher than the boiling point of the Ga₂O gas. The temperature of raw material chamber 100 is preferably lower than the temperature of growth chamber 111. As described later, when second heater 115 heats growth chamber 111, the temperature of raw material chamber 100 is preferably less than 1800° C., for example. Starting group III element source 105 is placed in raw material boat 104 disposed in raw material reaction room 101. Raw material boat 104 preferably has a shape capable of increasing the contact area between the reactive gas and starting group III element source 105. Raw material boat 104 preferably has a multi-stage dish shape to prevent starting group III element source 105 and the reactive gas from passing through raw material reaction room 101 in a non-contact state, for example.

### Multistage Raw Material Boat

FIG. 3A is a schematic sectional view illustrating an example of a structure of raw material boat 104 of multistage, here, four stage, and FIG. 3B is a schematic sectional view illustrating an example in which each stage of the raw material boat in FIG. 3A is filled with Ga. Raw material boat 104 of each stage includes channel pipe 124 through which gas passes. From the viewpoint of improving the contact probability between Ga and the reactive gas, it is preferable that the uppermost raw material boat has a structure including rectification lid 126. FIG. 3B is a conceptual diagram of the raw material boat when Ga is filled. As illustrated in FIG. 3B, a space other than channel pipe 124 is filled with Ga. The filling amount of Ga is preferably more than or equal to 5 mm in liquid level from the viewpoint of preventing Ga from aggregating and reducing the surface area.

Since each stage of the raw material boat is filled with a starting group III element source, for example, liquid Ga, each stage has a planar shape perpendicular to the vertical direction, and the multistage raw material boat is configured by vertically stacking each stage along the vertical direction.

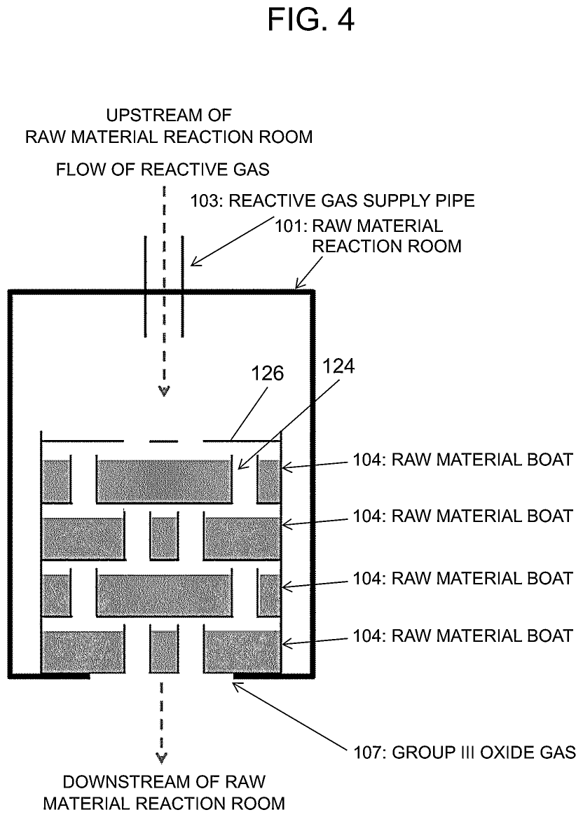

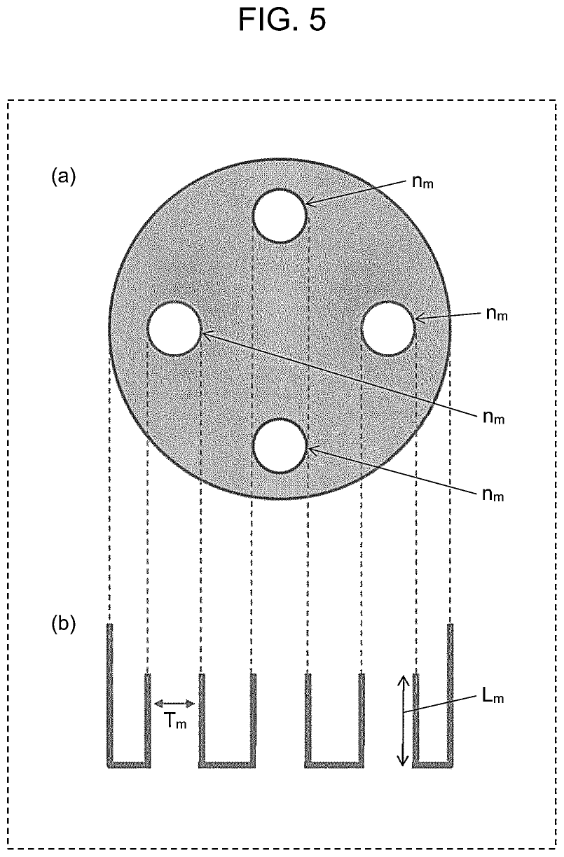

FIG. 4 is a schematic sectional view illustrating an example of a case where multistage raw material boat 104 is installed in raw material reaction room 101. The multistage raw material boat has a structure in which the reactive gas flows through each stage in series from the upstream side to the downstream side and does not flow back in raw material reaction room 101. Specifically, as illustrated in FIG. 4, the flow of the reactive gas flows in from reactive gas supply pipe 103 on the upstream side (low temperature side) of raw material reaction room 101, flows into the multistage raw material boat from the rectification lid side, and is discharged from group III element oxide gas discharge port 107 on the downstream (high temperature side) of raw material reaction room 101.

At this time, the size of raw material boat 104 can be formulated as follows.

$$\begin{matrix}[ Mathematical Formula 2 ] & \\ \frac{{d}_{G a N} \times W \times t}{[ G a N ]} < {\sum }_{m = 1}^{k} \frac{{d}_{G a} \times ( {S}_{m} - {n}_{m} \times {T}_{m} ) \times {l}_{m}}{[ G a ] \times y} & ( III )\end{matrix}$$

Here, d_{Gan} and d_{Ga} are mass densities of GaN and Ga, W is a surface area of seed substrate 116, t is a thickness of a GaN crystal to be grown, k is a total number of stages of the raw material boat, m is a variable representing the number of a stage when the lowermost stage of the raw material boat is the first stage and the uppermost stage is the k-th stage, Sₘ is a surface area of the raw material boat including the channel pipe, nₘ is the number of channel pipes of each raw material boat, Tₘ is a sectional area of the channel pipe, lₘ is a filling depth of Ga, Lₘ is a height of the raw material boat, y is a Ga yield of GaN crystals to be grown, [GaN] and [Ga] are a molecular weight and an atomic weight of gallium nitride and gallium. The molecule on the left side of Formula (III) represents the mass of the grown GaN crystal. Thus, the left side of Formula (III) is the substance amount (number of moles) of the grown GaN crystal. On the other hand, the value obtained by dividing the molecule on the right side of Formula (III) by the Ga yield y represents the mass of Ga required in each stage of raw material boat 104. Thus, the value obtained by dividing the mass by the atomic amount of Ga represents the substance amount of Ga in each stage. That is, the right side of Formula (III) is the sum (number of moles) of the required Ga substance amount. Formula (III) shows a relationship in which the sum of required Ga substance amount is larger than the substance amount of GaN crystal to be grown.

Here, each variable in Formula (III) satisfies the following relationship.

$$\begin{matrix}[ Mathematical Formula 3 ] & \\ {l}_{m} < {L}_{m} & ( IV )\end{matrix}$$

$$1 \leq m \leq k \qquad ( V )$$

Formula (IV) is a relational expression indicating that the height of raw material boat 104 is larger than the liquid level of Ga, and Formula (V) is an expression indicating that the number of stages of raw material boats 104 is from the first stage to the k-th stage.

In addition, only the sectional area Tₘ of the channel pipe may be any numerical value in one raw material boat as long as the following Formula (VI) is satisfied.

$$\begin{matrix}[ Mathematical Formula 4 ] & \\ {T}_{m} < \frac{{S}_{m}}{{n}_{m}} & ( VI )\end{matrix}$$

Further, nₘ preferably satisfies the following Formula (VII) from the viewpoint of improving the contact probability between the reactive gas and Ga.

$$\begin{matrix}[ Mathematical Formula 5 ] & \\ {n}_{m} \geq 2 & ( VII )\end{matrix}$$

Further, as illustrated in FIG. 4, raw material boat 104 installed in raw material reaction room 101 preferably has a structure in which the reactive gas does not flow back from the downstream side to the upstream side of the raw material reaction room in the raw material boat. This is because first heater 106 heats raw material reaction room 101, but third heater 110 heats connection pipe 109 so that the temperature of connection pipe 109 is not lower than the temperature of raw material chamber 100, and thus the temperature of raw material reaction room 101 is low on the upstream side and high on the downstream side. The upstream side of raw material reaction room 101 is the reactive gas supply pipe 103 side, and the downstream side of the raw material reaction room 101 is the group III element oxide gas discharge port 107 side. That is, the structure in which the reactive gas does not flow back is a structure in which the reactive gas flows from the low temperature side toward the high temperature side in raw material boat 104. When backflow occurs, the gas flows from the high temperature side to the low temperature side, and thus the reverse reaction of Formula (I) is likely to occur. When the reverse reaction occurs, Ga droplets are generated, which may cause deterioration in quality of the group III nitride crystal and a decrease in the generation amount of the group III oxide gas.

FIG. 5 illustrates an example of the structure of raw material boat 104 in one stage stacked in multiple stages. An example illustrated in FIG. 5 is a case where the number nₘ of the channel pipe is four. Part (a) of FIG. 5 is a conceptual surface view of the Ga filling surface side of raw material boat 104. Part (b) of FIG. 5 is a schematic sectional view of raw material boat 104. Here, an example of the way of stacking multistage raw material boats 104 will be described. For example, to improve the contact area between the reactive gas and Ga, it is preferable that the raw material boats stacked in multiple stages are not present at positions where the channel pipes of the respective stages coincide with the channel pipes of the vertically adjacent stages in plan view. If the channel pipe of each stage is located at a position coinciding with the channel pipe of the vertically adjacent stage in plan view, there is a high possibility that the reactive gas passes through each stage in a non-contact state with Ga and is discharged from group III element oxide gas discharge port 107. In addition, from the viewpoint of improving the contact probability between the reactive gas and Ga, it is preferable that the plurality of channel pipes in each stage of the raw material boat stacked in multiple stages are provided apart from each other in the same stage.

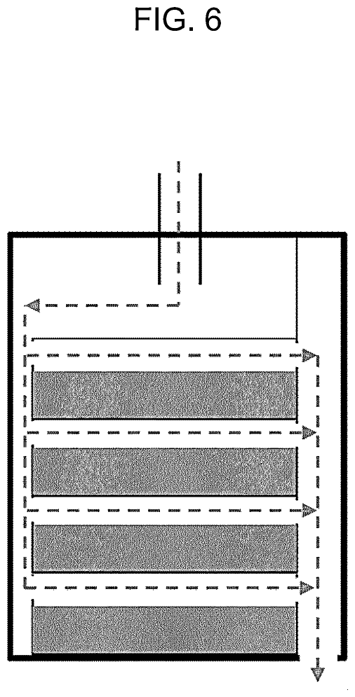

Further, in this multistage raw material boat, as illustrated in FIG. 4, the reactive gas flows in series from the upstream side to the downstream side in each stage. On the other hand, in a case where the multistage raw material boat has a structure in which the reactive gas flows in parallel from the upstream side to the downstream side in each stage as illustrated in FIG. 6, there is a possibility that the contact probability between the reactive gas and starting group III element source 105 decreases.

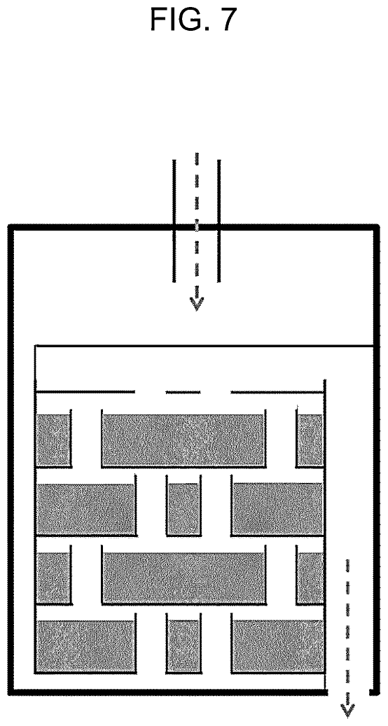

Further, in this multistage raw material boat, as described above, the reactive gas does not flow back from the downstream side to the upstream side of the raw material reaction room in the raw material boat. Specifically, as illustrated in FIG. 4, the reaction gas has a structure in which the reactive gas flows so as to trace the temperature gradient from the low temperature side of raw material reaction room 101 toward the high temperature side of raw material reaction room 101. As illustrated in FIG. 7, the reactive gas flows in series in each stage from the upstream side to the downstream side of the raw material boat, but when the upstream side of the raw material boat is the high temperature side of the downstream of the raw material reaction room and the downstream side of the raw material boat is the high temperature side of the upstream of the raw material reaction room, the reactive gas flows back in the raw material reaction room. When the reactive gas flows back from the high temperature side to the low temperature side of the raw material reaction room like this, the reactive gas flows from the high temperature side of raw material reaction room 101 toward the low temperature side of raw material reaction room 101. In this case, the reverse reaction of Formula (1) is likely to occur, which may cause quality deterioration of the group III nitride crystal and a decrease in the generation amount of the group III oxide gas.

In addition, the flow rate of the reactive gas can be adjusted in order to realize a desired production amount of the group III oxide gas. The flow rate of the reactive gas can be adjusted by changing sectional area Tₘ of the channel pipe in raw material boat 104, the number of the channel pipes nₘ, the number of stages k of the raw material boat, and the like. For example, to improve the reaction efficiency between the reactive gas and Ga, it is possible to reduce the flow rate of the reactive gas. By reducing the flow rate, the contact probability between the reactive gas and Ga can be improved, and the production amount of the group III oxide gas is improved. For example, by reducing sectional area Tₘ of the channel pipe in raw material boat 104, the average flow rate of the reactive gas in raw material reaction room 101 can be reduced. From the viewpoint of improving the reaction efficiency between the reactive gas and Ga, the sectional area Tₘ of the channel pipe is preferably less than or equal to 100 mm². The average flow rate of the reactive gas in raw material reaction room 101 can also be reduced by increasing the number of the channel pipes nₘ in raw material boat 104. The average flow rate of the reactive gas in raw material reaction room 101 can also be reduced by increasing the number of stages k of the raw material boat. In addition, it is also possible to suppress the flow rate by reducing the flow rate of N₂ gas or H₂ gas used as the carrier gas.

Methods for producing the group III element oxide gas are roughly classified into a method for reducing starting group III element source 105 and a method for oxidizing starting group III element source 105. For example, in the reduction method, an oxide (for example, Ga₂O₃) is used as starting group III element source 105, and a reducing gas (for example, H₂ gas, CO gas, CH₄ gas, C₂H₆ gas, H₂S gas, or SO₂ gas) is used as the reactive gas.

In the oxidation method, an oxide (for example, liquid Ga) is used as starting group III element source 105, and an oxidizing gas (for example, H₂O gas, O₂ gas, CO gas, NO gas, N₂O gas, NO₂ gas, or N₂O₄ gas) is used as the reactive gas. As starting group III element source 105, an In source or an Al source may be used in addition to the Ga source. As the first carrier gas, an inert gas, H₂ gas, or the like may be used.

In the group III element oxide gas supply step, the Ga₂O gas generated in the group III element oxide gas generation step is supplied to growth chamber 111 via gas discharge port 108, connection pipe 109, and gas supply port 118. When the temperature of connection pipe 109 connecting raw material chamber 100 and growth chamber 111 is lower than the temperature of raw material chamber 100, a reverse reaction of the reaction for generating the group III element oxide gas occurs, and starting group III element source 105 may precipitate in connection pipe 109. Thus, connection pipe 109 is preferably heated by third heater 110 to have a temperature not lower than the temperature of raw material chamber 100.

In the nitrogen element-containing gas supply step, the nitrogen element-containing gas is supplied from nitrogen element-containing gas supply port 113 to growth chamber 111. Examples of the nitrogen element-containing gas include NH₃ gas, NO gas, NO₂ gas, N₂O gas, N₂O₄ gas, N₂H₂ gas, and N₂H₄ gas.

In the group III nitride crystal generation step, the raw material gas supplied into growth chamber 111 through each supply step is caused to react to grow a group III nitride crystal on seed substrate 116. Second heater 115 preferably heats growth chamber 111 to a temperature at which the group III element oxide gas and the nitrogen element-containing gas react with each other. At this time, to prevent the occurrence of a reverse reaction of the reaction for generating the group III element oxide gas, it is preferable to control the temperature of growth chamber 111 so that the temperature of growth chamber 111 does not become lower than the temperature of raw material chamber 100 and the temperature of connection pipe 109. The temperature of growth chamber 111 heated by second heater 115 is preferably from 1000° C. to 1800° C., inclusive.

Mixing the group III element oxide gas supplied to growth chamber 111 through the group III element oxide supply step and the nitrogen element-containing gas supplied to growth chamber 111 through the nitrogen element-containing gas supply step upstream of seed substrate 116 allows a group III nitride crystal to grow on seed substrate 116.

Examples of seed substrate 116 include gallium nitride, gallium arsenide, silicon, sapphire, silicon carbide, zinc oxide, gallium oxide, and ScAlMgO₄.

As the second carrier gas, an inert gas, H₂ gas, or the like may be used.

Unreacted group III element oxide gas and nitrogen element-containing gas, and the first carrier gas, the second carrier gas, and the third carrier gas are discharged from discharge port 119.

### EXAMPLES

### Overview of Examples and Comparative Examples

A group III nitride crystal was grown using a growth furnace that is a device for producing a group III nitride crystal illustrated in FIG. 1. Here, GaN was grown as the group III nitride crystal. A liquid Ga was used as the starting Ga source, Ga was caused to react with H₂O gas as the reactive gas, and the obtained Ga₂O gas was used as the group III element oxide gas. NH₃ gas was used as the nitrogen element-containing gas, and a mixture of H₂ gas and N₂ gas was used as the first carrier gas and the second carrier gas. As the seed substrate, a GaN self-standing substrate was used. The growth time was 1 hour for verification. The supply amount of Ga was estimated from the weight change of Ga.

### Comparative Example 1

In Comparative Example 1, a reactor having the structure of FIG. 6 in which flow paths are arranged in parallel with respect to a multistage raw material boat was used.

As growth conditions, the temperature of the growth chamber was set to 1230° C., and the temperature of the raw material chamber was set to 1185° C. To raw material reaction room 101, H₂O gas, H₂ gas, and N₂gas were supplied at 0.04 L/min, 3.96 L/min, and 1.00 L/min, respectively. The supply amount of generated Ga was 8.42 g/h. The growth rate of the grown GaN crystal was 49.7 μm/h. Further, the X-ray rocking curve of GaN (0002) was evaluated using an XRD device, and the half width was measured and found to be 105 arcsec.

### Comparative Example 2

In Comparative Example 2, a reactor having the structure of FIG. 7 in which the gas flowing in the multistage raw material boat flows back in raw material reaction room 101 was used. At this time, the number of the channel pipes nₘ was set to 4.

As growth conditions, the temperature of the growth chamber was set to 1230° C., and the temperature of the raw material chamber was set to 1185° C. To raw material reaction room 101, H₂O gas, H₂ gas, and N₂ gas were supplied at 0.04 L/min, 3.96 L/min, and 1.00 L/min, respectively. The supply amount of generated Ga was 9.97 g/h. The growth rate of the grown GaN crystal was 58.8 μm/h. Further, the X-ray rocking curve of GaN (0002) was evaluated using an XRD device, and the half width was measured and found to be 80 arcsec.

### Comparative Example 3

In Comparative Example 3, a reactor having the structure of FIG. 7 in which the gas flowing in the multistage raw material boat flows back in raw material reaction room 101 was used. At this time, the number of the channel pipes nm was set to 1.

As growth conditions, the temperature of the growth chamber was set to 1230° C., and the temperature of the raw material chamber was set to 1185° C. To raw material reaction room 101, H₂O gas, H₂ gas, and N₂ gas were supplied at 0.04 L/min, 3.96 L/min, and 1.00 L/min, respectively. The supply amount of generated Ga was 4.35 g/h. The growth rate of the grown GaN crystal was 21.9 μm/h. Further, the X-ray rocking curve (XRC) of GaN (0002) was evaluated using an XRD device, and the half width (FWHM) was measured and found to be 152 arcsec.

### Example 1

In Example 1, a reactor having the structure of FIG. 4 in which the gas flowing through the multistage raw material boat flows from the upstream side to the downstream side in raw material reaction room 101 is used. At this time, the number of the channel pipes nm was set to 4.

As growth conditions, the temperature of the growth chamber was set to 1230° C., and the temperature of the raw material chamber was set to 1185° C. To raw material reaction room 101, H₂O gas, H₂ gas, and N₂ gas were supplied at 0.04 L/min, 3.96 L/min, and 1 L/min, respectively. The supply amount of generated Ga was 11.30 g/h. The growth rate of the grown GaN crystal was 70.4 μm/h. Further, the X-ray rocking curve of GaN (0002) was evaluated using an XRD device, and the half width was measured and found to be 64 arcsec.

### Summary of Examples and Comparative Examples

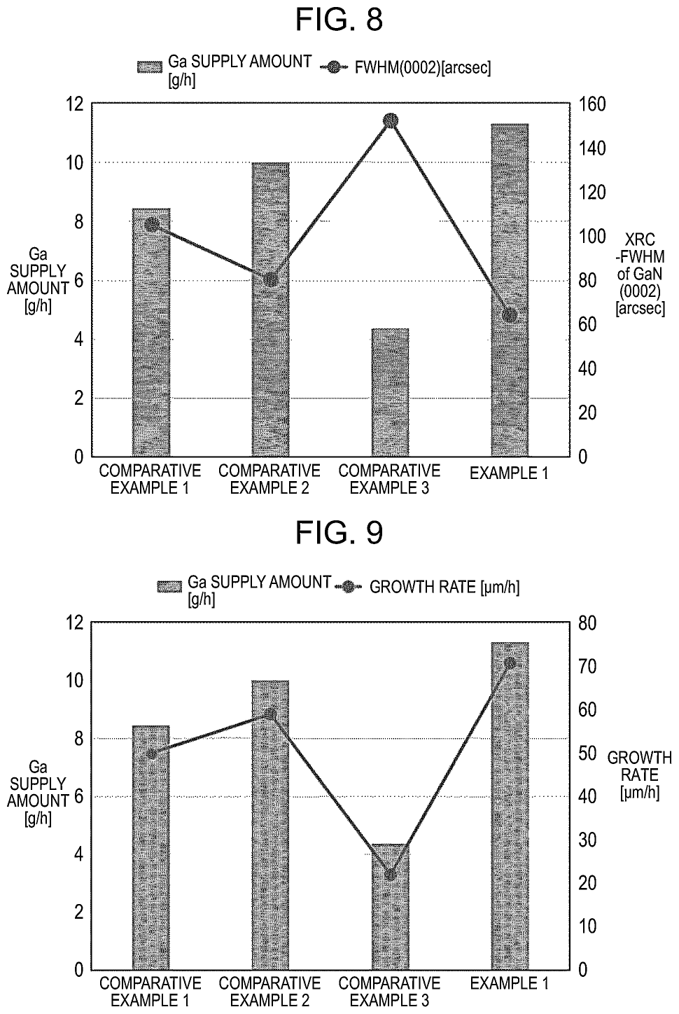

FIG. 8 illustrates a list of results of XRC-FWHM of GaN (0002) for which the Ga supply amount and crystal mosaicism were evaluated in Comparative Examples and Examples. It can be seen that the XRC-FWHM decreases as the Ga supply amount increases. This is because of an increase in the reaction amount between Ga and H₂O gas and a suppression of supply of liquid Ga to the growth chamber.

FIG. 9 illustrates a list of results of the Ga supply amount and the growth rate in Comparative Examples and Examples. It can be seen that the growth rate increases as the Ga supply amount increases. This is because the generation of Ga₂O as a Ga source of the GaN crystal improved.

To summarize these results, by using a multistage Ga raw material boat and further forming a flow from the upstream side to the downstream side, the reaction amount of Ga as a starting group III element source and H₂O gas as a reactive gas can be improved, and generation of liquid Ga due to the reverse reaction of Formula (I) is suppressed. This makes it possible to achieve both of improvement in the quality of the GaN crystal to be grown and improvement in the growth rate of the GaN crystal.

### INDUSTRIAL APPLICABILITY

The device for producing a group III nitride crystal according to the present disclosure, including a structure of promoting heat release from the back surface side of the seed substrate, can suppress generation of polycrystals and can produce a high-quality group III nitride crystal.

### REFERENCE MARKS IN THE DRAWINGS

100 raw material chamber
101 raw material reaction room
102 first carrier gas supply port
103 reactive gas supply pipe
104 raw material boat
105 starting group III element source
106 first heater
107 group III element oxide gas discharge port
108 gas discharge port
109 connection pipe
110 third heater
111 growth chamber
112 third carrier gas supply port
113 nitrogen element-containing gas supply port
114 second carrier gas supply port
115 second heater
116 seed substrate
117 substrate susceptor
118 gas supply port
119 discharge port
120 substrate tray
121 rotary shaft
122 fourth heater
124 channel pipe
126 rectification lid
200 device for producing group III nitride crystal

1. A device for producing a group III nitride crystal, the device comprising:
a raw material chamber that generates a group III element oxide gas; and
a growth chamber that reacts the group III element oxide gas supplied from the raw material chamber with a nitrogen element-containing gas to generate a group III nitride crystal on a seed substrate,
wherein the raw material chamber includes
a raw material reaction room, and
a multistage raw material boat that includes stages, is provided in the raw material reaction room, is filled with a starting group III element source, and causes a reactive gas to flow to react with the starting group III element source to generate the group III element oxide gas, and
the multistage raw material boat includes, in each of the stages, at least two or more channel pipes through which the reactive gas flows, the at least two or more channel pipes connecting the stage to an adjacent stage among the stages.

2. The device for producing a group III nitride crystal according to claim 1, wherein
the reactive gas passing inside the raw material chamber flows from an upstream side to a downstream side in the raw material reaction room, and
the multistage raw material boat includes, in each stage, a passage through which the reactive gas flows, the passage being disposed from an upstream low-temperature side toward a downstream high-temperature side of the raw material reaction room.

3. The device for producing a group III nitride crystal according to claim 1, wherein the multistage raw material boat satisfies relationships of Formulas (1) to (5):
$$\frac{{d}_{G a N} \times W \times t}{[ G a N ]} < {\sum }_{m = 1}^{k} \frac{{d}_{G a} \times ( {S}_{m} - {n}_{m} \times {T}_{m} ) \times {l}_{m}}{[ G a ] \times y} \qquad ( 1 )$$
$${l}_{m} < {L}_{m} \qquad ( 2 )$$
$$1 \leq m \leq k \qquad ( 3 )$$
$${T}_{m} < \frac{{S}_{m}}{{n}_{m}} \qquad ( 4 )$$
$${n}_{m} \geq 2 \qquad ( 5 )$$
where d_{Gan} is a mass density of gallium nitride, d_{Ga} is a mass density of gallium, [GaN] is a molecular weight of gallium nitride, [Ga] is an atomic weight of gallium, W is a surface area of a wafer, t is a thickness of a grown GaN crystal, Sₘ is a surface area of the raw material boat of an m-th stage, nₘ is a number of channel pipes of the raw material boat of the m-th stage, Tₘ is a sectional area of the channel pipe of the raw material boat of the m-th stage, lₘ is a height of the raw material boat of the m-th stage, y is a yield of Ga in GaN crystal growth, and k is a total number of stages of the multistage raw material boat.

4. The device for producing a group III nitride crystal according to claim 1, wherein the multistage raw material boat has a structure in which the at least two or more channel pipes of the respective stages are not at positions that coincide with the at least two or more channel pipes of the stage with respect to a vertically adjacent stage among the stages in plan view.

5. The device for producing a group III nitride crystal according to claim 1, wherein a sectional area Tm of each of the at least two or more channel pipes is less than or equal to 100 mm².

6. A method for producing a group III nitride crystal, the method comprising:
reacting a group III element source with a reactive gas to generate a group III element oxide gas; and
reacting the group III element oxide gas with a nitrogen element-containing gas to generate a group III nitride crystal on a seed substrate, wherein
in generation of the group III element oxide gas, a flow amount of a carrier gas flowing in addition to the group III element source and the reactive gas is reduced to suppress a flow rate of the reactive gas.
